(19) United States
(12) Patent Application Publication
(10) Pub. No.: US 2025/0209227 A1
(43) Pub. Date: Jun. 26, 2025

(54) System and Methods for Generating Water Efficient Landscape Designs

(71) Applicant: Water Efficient Garden LLC, San Jose, CA (US)

(72) Inventors: Xiaoke Tao, Cupertino, CA (US); Ishika Sanghi, Chicago, IL (US)

(73) Assignee: Water Efficient Garden LLC, San Jose, CA (US)

(21) Appl. No.: 18/999,607

(22) Filed: Dec. 23, 2024

Related U.S. Application Data
(60) Provisional application No. 63/614,722, filed on Dec. 26, 2023.

(51) Int. Cl. G06F 30/13; G06Q 50/06

(52) U.S. Cl. CPC G06F 30/13; G06Q 50/06

(57) ABSTRACT

A landscape design system and associated methods are disclosed for dynamically generating an at least one water efficient landscape design, consisting of a plurality of water efficient plants, for an at least one site. In at least one embodiment, a computing system is in selective communication with an at least one landscape database. The computing system gathers from an at least one user and the at least one landscape database various details related to the site and the user's plant preferences, then accesses a plant table within the at least one landscape database to obtain select details on a plurality of plants to potentially 10 include in the at least one landscape design. Based on the gathered details, the computing system populates a plant selection list and communicates the plant selection list as a landscape design report to the at least one user.

### RELATED APPLICATIONS

This application claims priority and is entitled to the filing date of U.S. provisional application Ser. No. 63/614,722, filed on Dec. 26, 2023. The contents of the aforementioned application are incorporated herein by reference.

### BACKGROUND

The subject of this patent application relates generally to landscape design, and more particularly to a system and associated methods for dynamically generating water efficient landscape designs.

Applicant hereby incorporates herein by reference any and all patents and published patent applications cited or referred to in this application.

By way of background, the process of generating a landscape design plan for a given piece of land (hereinafter referred to as a “site” for simplicity purposes), including plant selection and placement, is traditionally performed manually. Specifically, the process traditionally requires a site visit by a designer in order to visually inspect the site, take measurements, take note of various factors like sun exposure and soil conditions, and talk to the site owner/client to determine which plant types and/or specific colors they prefer. Based on that site visit and gathering of information, the designer defines a style for the landscape and creates a layout. The designer then chooses the plants that will meet the design and the client's requirements. The designer selects the plants based on their height, width, sun exposure, soil condition, flower color, etc. that the client indicated. If the project is a “lawn to garden” rebate project, the designer will also need to select plants from several plant lists provided by the city and/or water district in which the site is located. Some plant lists have up to 2,700+ plants, making the look-up a very time-consuming process.

After the plants are selected, the designer decides on the quantity of each plant. Many rebate programs have requirements for the total coverage of the plants in the new landscape, which must be at least 50% or higher of the original landscape's size. If a project is to receive rebates, the designer must look up the coverages of each plant from the water agency's designated plant lists, perform the calculations, and add them up to come to a total coverage amount, and then compare that number against the required 50% coverage requirement. If the total coverage does not meet the required square footage, then the design must either adjust the plant types in the design plan, or the quantities of the plants, or both, then achieve a total coverage that can meet the rebate's requirement.

The above-described traditional process has a number of problems. For example, the researching, designing, looking up the square footage, and calculating to meet the rebate requirements are very time-consuming, making the overall landscape design process highly inefficient. This, in turn, hinders many people from taking up landscape transformation projects, which are critical to reducing urban water usage and meeting water-saving goals. Additionally, the traditional plant selection process is driven very much by the designer's and the clients' personal tastes in plants. The plants may or may not be the optimal choice from all perspectives; for example, the selection may have very few or no native plants, or fail to consider the biodiversity value of a specific plant. Not only that, but the above-described traditional process also typically incorporates some amount of grass/lawn and non-native plants in the designs that have medium to high water requirements, which limits water conservation and biodiversity results or effects. Thus, there remains a need for improved systems and processes for dynamically generating water efficient landscape designs for a given site that promotes and significantly improves both water conservation efforts as well as biodiversity and pollination.

Aspects of the present invention fulfill these needs and provide further related advantages as described in the following summary.

It should be noted that the above background description includes information that may be useful in understanding aspects of the present invention. It is not an admission that any of the information provided herein is prior art or relevant to the presently claimed invention, or that any publication specifically or implicitly referenced is prior art.

### SUMMARY

Aspects of the present invention teach certain benefits in construction and use which give rise to the exemplary advantages described below.

The present invention solves the problems described above by providing a landscape design system and associated methods for dynamically generating an at least one water efficient landscape design, consisting of a plurality of water efficient plants, for an at least one site. In at least one embodiment, a computing system is configured for receiving and processing select data related to each of the at least one landscape design and corresponding site, the computing system in selective communication with an at least one landscape database. The computing system gathers from an at least one user and the at least one landscape database one or more of a site location, site dimensions, a site orientation, a minimum plant height, a maximum plant height, a sun exposure, color preferences, a native preference, a tree quantity, a plant preference list, an existing plant list, and a plant selection list associated with the at least one site. The computing system stores one or more of the site location, site dimensions, site orientation, minimum plant height, maximum plant height, sun exposure, color preferences, native preference, tree quantity, plant preference list, existing plant list, and plant selection list for each of the at least one site in a corresponding design record. The computing system accesses a plant table within the at least one landscape database to obtain select details on a plurality of plants to potentially include in the at least one landscape design, said details including one or more of a plant origin, a common name, a botanical name, a plant type, a specimen plant, plant colors, a plant form, a minimum height, a maximum height, a coverage area, a sun requirement, a water requirement, and a bio value.

The computing system populates the plant selection list for the at least one site based on data contained in the corresponding design record and the at least one plant table, the process of populating said plant selection list comprising the steps of: (a) the computing system accessing the at least one plant table and identifying all plants within the plant table that are compatible with an environment of the site location associated with said site; (b) the computing system determining which of said identified plants within the plant table satisfy each of the minimum plant height, maximum plant height, color preferences, native preference, and plant preference list specified in the corresponding design record, and adding each of said identified plants to a compatible plant set; (c) the computing system ordering the plants within the compatible plant set by their respective maximum height, selecting a pre-determined number of plants from the compatible plant set having the greatest maximum height, and adding said plants to the plant selection list; (d) the computing system generating a shrub list comprising all plants in the compatible plant set having a “shrub” plant type and a plant color that matches one or more of the color preferences in the corresponding design record; (e) the computing system adding a specimen plant from the shrub list to the plant selection list; (f) the computing system ordering the plants within the shrub list by their respective maximum height, selecting a pre-determined number of plants from the shrub list having the greatest maximum height, and adding said plants to the plant selection list; (g) the computing system ordering the plants within the shrub list by their respective bio value, selecting a pre-determined number of plants having the greatest bio value, and adding said plants to the plant selection list; (h) the computing system selecting a pre-determined number of plants from the shrub list having the next greatest bio value and a different plant form as compared to the plants chosen in step (g), and adding said plants to the plant selection list; (i) the computing system selecting a pre-determined number of plants from the shrub list having the next greatest bio value and a different plant color as compared to the plants chosen in step (h), and adding said plants to the plant selection list; (j) the computing system selecting a pre-determined number of plants from the shrub list having the next greatest bio value as compared to the plants chosen in step (i), and adding said plants to the plant selection list; (k) the computing system generating a perennial list comprising all plants in the compatible plant set having a “perennial” plant type and a plant color that matches one or more of the color preferences in the corresponding design record; (l) the computing system ordering the plants within the perennial list by their respective maximum height, selecting a pre-determined number of plants from the perennial list having the greatest maximum height, and adding said plants to the plant selection list; (m) the computing system selecting a pre-determined number of plants from the perennial list having the next greatest maximum height and a different plant color as compared to the plants chosen in step (l), and adding said plants to the plant selection list; (n) the computing system generating a groundcover list comprising all plants in the compatible plant set having a “groundcover” plant type and a plant color that matches one or more of the color preferences in the corresponding design record; (o) the computing system ordering the plants within the groundcover list by their respective maximum height, selecting a pre-determined number of plants from the groundcover list having the greatest maximum height, and adding said plants to the plant selection list; (p) the computing system selecting a pre-determined number of plants from the groundcover list having the next greatest maximum height and a different plant color as compared to the plants chosen in step (o), and adding said plants to the plant selection list; (q) upon the computing system determining that the tree quantity value of the corresponding design record is greater than zero: the computing system generating a tree list comprising all plants in the compatible plant set having a “tree” plant type; and the computing system ordering the plants within the tree list by their respective bio value, selecting a pre-determined number of plants from the tree list having the greatest bio value, and adding said plants to the plant selection list. The computing system then communicates the plant selection list as a landscape design report to the at least one user.

Other features and advantages of aspects of the present invention will become apparent from the following more detailed description, taken in conjunction with the accompanying drawings, which illustrate, by way of example, the principles of aspects of the invention.

### BRIEF DESCRIPTION OF THE DRAWINGS

The accompanying drawings illustrate aspects of the present invention. In such drawings:

FIG. 1 is a simplified schematic view of an exemplary landscape design system, in accordance with at least one embodiment;

FIG. 2 is a flow diagram of an exemplary method for dynamically generating a water efficient landscape design, in accordance with at least one embodiment;

FIG. 3 is an architecture diagram of an exemplary landscape record, in accordance with at least one embodiment;

FIG. 4 is an illustration of an exemplary plant table, in accordance with at least one embodiment;

FIG. 5 is a flow diagram of an exemplary method for dynamically selecting an at least one shrub plant for the water efficient landscape design, in accordance with at least one embodiment;

FIG. 6 is a flow diagram of an exemplary method for dynamically selecting an at least one perennial plant for the water efficient landscape design, in accordance with at least one embodiment;

FIG. 7 is a flow diagram of an exemplary method for dynamically selecting an at least one groundcover plant for the water efficient landscape design, in accordance with at least one embodiment;

FIG. 8 is a flow diagram of an exemplary method for dynamically selecting an at least one tree for the water efficient landscape design, in accordance with at least one embodiment; and

FIG. 9 is an illustration of an exemplary landscape design report, in accordance with at least one embodiment.

The above described drawing figures illustrate aspects of the invention in at least one of its exemplary embodiments, which are further defined in detail in the following description. Features, elements, and aspects of the invention that are referenced by the same numerals in different figures represent the same, equivalent, or similar features, elements, or aspects, in accordance with one or more embodiments.

### DETAILED DESCRIPTION

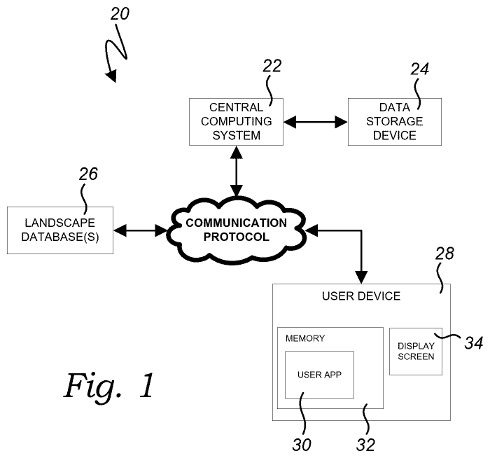

Turning now to FIG. 1, there is shown a simplified schematic view of an exemplary embodiment of a landscape design system 20 configured for dynamically generating a water efficient landscape design, consisting of water efficient plants and trees (collectively hereinafter referred to as “plants” for simplicity purposes), for a site. At the outset, it should be noted that the term “site” as used herein is intended to include any type of land—residential, commercial, industrial, municipal, etc.—where there is a desire to create a water efficient landscape thereon. Thus, the system 20 may be utilized in virtually any situation where there is a desire to create a water efficient landscape. Accordingly, each of these contexts are intended to fall within the scope of the term “site” as used herein.

In at least one embodiment, the system 20 provides a central computing system 22 configured for receiving and processing select data related to an at least one site along with the generated at least one landscape design for the at least one site, as discussed further below. In at least one embodiment, the system 20 further provides an at least one data storage device 24 in selective communication with the computing system 22 and configured for storing said data related to each of the at least one landscape design and site. In at least one embodiment, the computing system 22 and data storage device 24 are one and the same—as such, it is intended that those terms as used herein are to be interchangeable with one another. In at least one embodiment, the computing system 22 is also in selective communication with an at least one database containing select data that can be utilized by the computing system 22 in generating the at least one water efficient landscape design for a given site (hereinafter collectively referred to as a “landscape database” 26 for simplicity purposes)—such as, for example, databases containing details on potentially viable plants and trees, databases containing geographic details relevant to the site, databases containing soil details relevant to the site, databases containing weather and climate details relevant to the site, databases containing rebate details relevant to the site, etc.—as discussed further below. In at least one embodiment, the at least one landscape database 26 is in the possession and/or control of the system 20. In at least one such embodiment, the at least one landscape database 26 is stored on the at least one data storage device 24. In at least one alternate embodiment, the at least one landscape database 26 is in the possession and/or control of a third party. In at least one embodiment, an at least one user device 28 is in selective communication with the computing system 22, as discussed further below.

In that regard, it should be noted that communication between each of the computing system 22, data storage device 24, landscape database 26, and user device 28 may be achieved using any wired- or wireless-based communication protocol (or combination of protocols) now known or later developed. As such, the present invention should not be read as being limited to any one particular type of communication protocol, even though certain exemplary protocols may be mentioned herein for illustrative purposes. Similarly, in at least one embodiment, communications between each of the computing system 22, data storage device 24, landscape database 26, and user device 28 may be encrypted using any encryption method (or combination of methods) now known or later developed. It should also be noted that the terms “computing system” and “user device” are each intended to include any type of computing or electronic device, now known or later developed, capable of substantially carrying out the functionality described herein—such as server computers, desktop computers, mobile phones, smartphones, laptop computers, tablet computers, personal data assistants, gaming devices, wearable devices, etc. As such, the system 20 should not be read as being limited to use with any one particular type of computing or electronic device, even though certain exemplary computing systems 22 and/or user devices 28 may be mentioned or shown herein for illustrative purposes.

In at least one embodiment, the computing system 22 contains the hardware and software necessary to carry out the exemplary methods for dynamically generating the at least one water efficient landscape design for a given site, as described herein. Furthermore, in at least one embodiment, the computing system 22 comprises a plurality of computing and/or electronic devices selectively working in concert with one another to carry out the exemplary methods for dynamically generating the at least one water efficient landscape design for a given site, as described herein. In at least one embodiment, the at least one user device 28 provides a user application 30 residing locally in memory 32 on the user device 28 (for example, as a standalone application on the user device 28), the user application 30 being configured for selectively communicating with the computing system 22, as discussed further below. In at least one alternate embodiment, the functionality provided by the user application 30 resides remotely in memory on the computing system 22 and/or data storage device 24, with the at least one user device 28 capable of accessing said functionality via an online portal hosted by (or at least in communication with) the computing system 22 and/or data storage device 24, either in addition to or in lieu of the user application 30 residing locally in memory 32 on the at least one user device 28. It should be noted that the term “memory” is intended to include any type of electronic storage medium (or combination of storage mediums) now known or later developed, such as local hard drives, RAM, flash memory, secure digital (“SD”) cards, external storage devices, network or cloud storage devices, integrated circuits, etc. Additionally, in at least one embodiment, each of the at least one user device 28 is in the possession of a user (such as the owner of the site or a landscape designer hired by the owner of the site, for example) who is desirous of utilizing the system 20 to dynamically generate at least one water efficient landscape design for a given site.

It also should be noted that, for simplicity purposes, the functionality provided by the user application 30 will be described herein as such—even though certain embodiments may provide said functionality through an online portal. It should also be noted that, for simplicity purposes, when discussing functionality and the various methods that may be carried out by the system 20 herein, the terms “computing system,” “user device” and “user application” are intended to be interchangeable. In that regard, in at least one further embodiment, the computing system 22 and user device 28 are one and the same. With continued reference to FIG. 1, in at least one embodiment, the at least one user device 28 provides an at least one display screen 34 for providing an at least one graphical user interface to assist the associated user in possession of said user device 28 to access and utilize the various functions provided by the system 20.

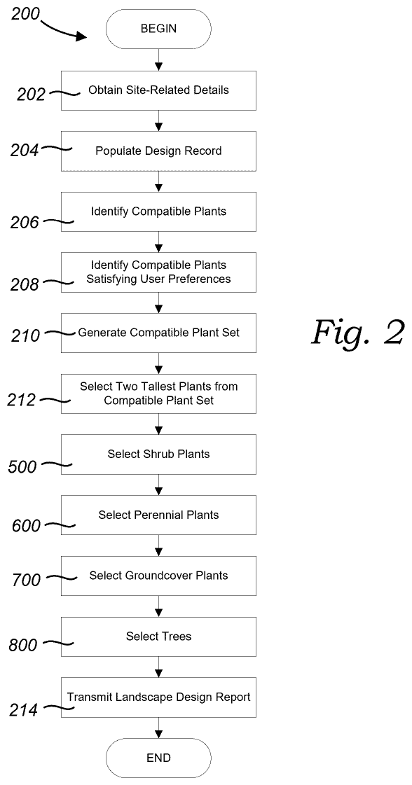

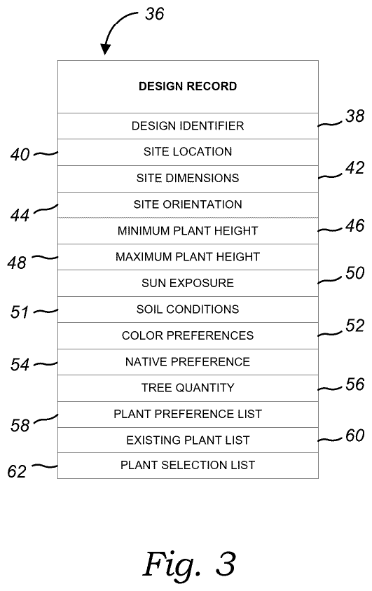

In at least one embodiment, as illustrated in the flow diagram of FIG. 2, through the user application 30 residing either locally in memory 32 on the at least one user device 28 or remotely on the computing system 22 and/or data storage device 24, the method of dynamically generating at least one water efficient landscape design for a given site entails the steps of the computing system 22 first gathering select site-related details from the user (202). In at least one such embodiment, the user application 30 provides a form via the at least one display screen 34 of the corresponding user device 28 through which the user is able to provide some or all of the site-related details. In at least one embodiment, the site-related details include one or more of a site location 40 (i.e., the geographic location of the site, represented as an address or GPS coordinates, for example), site dimensions 42 (i.e., the length, width, and shape of the area of the site), a site orientation 44 (i.e., the cardinal direction of the site), a minimum plant height 46 (i.e., the user's preference on the minimum height 82 of each of the plants to be used in the landscape design), a maximum plant height 48 (i.e., the user's preference on the maximum height 84 of each of the plants to be used in the landscape design), a sun exposure 50 (i.e., the level of sun exposure for the site, represented as “full sun,” “partial sun,” and “full shade,” for example), soil conditions 51 (i.e., the type of soil present at the site, represented as “sandy soil,” “clay soil,” “loamy soil,” “peat soil,” “silt soil,” “chalky soil,” or “hydric soil,” for example), color preferences 52 (i.e., the user's preference on the possible colors of each of the plants to be used in the landscape design), a native preference 54 (i.e., the user's preference on whether the plants to be used in the landscape design should be native to the geographic location of the site), a tree quantity 56 (i.e., the number of trees the user would like to include in the landscape design), a plant preference list 58 (i.e., a list of the specific types of plants and/or trees that the user would like to include in the landscape design), an existing plant list 60 (i.e., a list of plants and/or trees that are already existing at the site), and a plant selection list 62 (i.e., a list of plants and/or trees that have been selected to be included in the landscape design). In at least one embodiment, as illustrated in FIG. 3, the select site-related details are stored in a corresponding design record 36 within the data storage device 24 (204), with the design record 36 having a unique design identifier 38 as compared to any other design record 36 stored within the data storage device 24.

In at least one further embodiment, sun exposure 50 of the site and each sub area

of the whole site (i.e., next to the fence, behind the tree) can be calculated automatically to indicate the sun exposure 50 for the site and each of the sub area. In at least one further embodiment, more factors, such as plant wellness from year 0 to year 5 will be added as a factor to consider by the computing system 22.

In at least one embodiment, the form provided by the user application 30 includes images of potential landscape design styles along with images of potential plants and trees, allowing the user to indicate which (if any) they would prefer. Based on those selections, the computing system 22 is capable of generating one or more of the minimum plant height 46, maximum plant height 48, color preferences 52, native preference 54, tree quantity 56 and plant preference list 58. In at least one such embodiment, the user first selects the image of the potential landscape design style they prefer, at which point the user application 30 presents the user with images of potential plants and trees that fit within the selected landscape design style, thereby better ensuring that the user selects plants and trees that will fit within their preferred landscape design style.

In at least one embodiment, the computing system 22 is capable of automatically determining one or more of the site-related details. For example, in at least one embodiment, the computing system 22 is capable of determining the sun exposure 50 based on the provided site location 40 and site orientation 44. In at least one embodiment, where the user fails to specify the minimum plant height 46 or maximum plant height 48, the computing system 22 will use a default value for the minimum plant height 46 and/or maximum plant height 48.

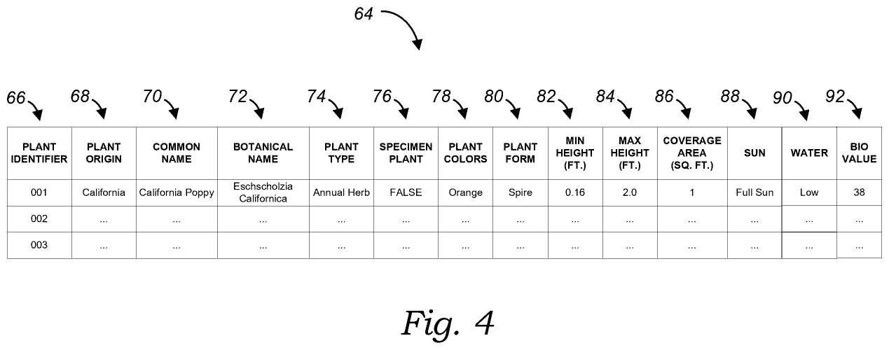

In at least one embodiment, the at least one landscape database 26 contains an at least one plant table 64 containing select details related to each plant that could potentially be used in the landscape design for a given site, the purpose for which is discussed further below. It should be noted that while the term “table” is used herein to describe certain exemplary data structures, in at least one embodiment, any other suitable data type or data structure, or combinations thereof, now known or later developed, capable of storing the appropriate data, may be substituted. Thus, the present invention should not be read as being so limited. In at least one embodiment, as illustrated in FIG. 4, the at least one plant table 64 contains, for each plant contained therein, at least one of a unique plant identifier 66 as compared to any other plant stored within the plant table 64, a plant origin 68 containing the geographic location of the corresponding plant's native origin, a common name 70 containing the common name of the corresponding plant, a botanical name 72 containing the botanical name of the corresponding plant, a plant type 74 containing the type or category of the corresponding plant (e.g., tree, shrub, perennial, groundcover, etc.), a specimen plant 76 containing a Boolean value as to whether the corresponding plant qualifies as a specimen plant 76 (i.e., a prime small tree or shrub that can function as a focus of interest in the landscape design), plant colors 78 containing the colors of the corresponding plant and any associated flowers said plant may produce, a plant form 80 containing the shape of the corresponding plant (e.g., fountain, mound, spire, movement, etc.), a minimum height 82 containing the minimum height 82 of the corresponding plant, a maximum height 84 containing the maximum height 84 of the corresponding plant, a coverage area 86 containing a coverage area 86 (in square feet, for example) provided by the corresponding plant, a sun requirement 88 containing the amount of sun required by the corresponding plant (e.g., full sun, partial sun, full shade, etc.), a water requirement 90 containing the amount of water required by the corresponding plant (e.g., extremely low, very low, low, moderate, high, etc. or, alternatively a percentage value relative to the water requirements of a traditional lawn or other plants that require relatively more water), and a bio value 92 containing a value that indicates the corresponding plant's capacity to support moths and other pollinators. In at least one embodiment, the bio value 92 for a given plant is calculated using the quantity of different types of moths and pollinators (i.e., birds, butterflies, bees and insects) that the plant is known to support. In at least one embodiment, one or more of the details contained in the plant table 64 is obtained by the computing system 22 from one or more third-party landscape databases 26.

In at least one embodiment, the computing system 22 populates the plant selection list 62 for the site based on the data contained in the corresponding design record 36 and the at least one plant table 64. In at least one such embodiment, based on the site location 40 in the corresponding design record 36, the computing system 22 accesses the at least one plant table 64 and identifies all plants that are compatible with the environment of the site location 40 (206). For each plant identified by the computing system 22 as being compatible with the environment of the site location 40, the computing system 22 determines whether those plants meet the other requirements/preferences specified by the user (208)—i.e., minimum plant height 46, maximum plant height 48, color preferences 52, native preference 54, tree quantity 56, and plant preference list 58. For each plant that meets the other requirements/preferences specified by the user, the computing system 22 adds said plants to a compatible plant set, with said compatible plant set containing one or more of the datapoints associated with said plants from the at least one plant table 64 (210). Once the computing system 22 has populated the compatible plant set, the computing system 22 orders the plants within the compatible plant set by maximum height 84 and then selects a pre-determined number of plants (based on the site dimensions 42, for example) having the greatest height—for example, the two tallest plants—and adds them to the plant selection list 62 (212).

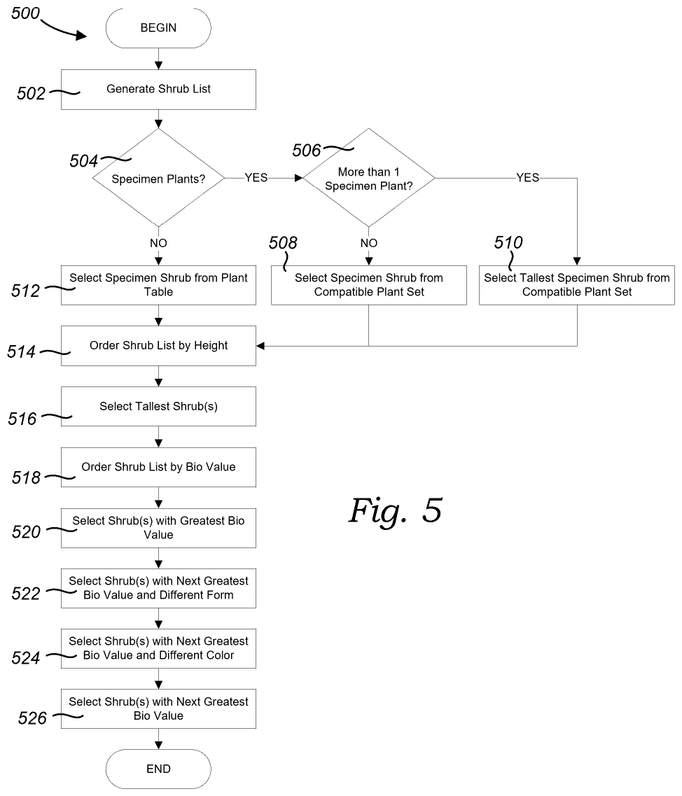

In at least one embodiment, as illustrated in the flow diagram of FIG. 5, the computing system 22 generates a shrub list comprising all plants in the compatible plant set having a “shrub” plant type 74 and a plant color 78 that matches one or more of the color preferences 52 in the corresponding design record 36 (502). If the computing system 22 determines that only a single plant in the shrub list is a specimen plant 76 (506), said plant is added to the plant selection list 62 (508). On the other hand, if the computing system 22 determines that two or more plants in the shrub list are specimen plants 76 (506), the specimen plant 76 having the greatest maximum height 84 value is selected and added to the plant selection list 62 (510). If the computing system 22 determines that no plants in the shrub list are a specimen plant 76 (504), the computing system 22 selects a “shrub” specimen plant 76 from the at least one plant table 64 (i.e., a plant that is not in the plant preference list 58) having a plant color 78 that matches one or more of the color preferences 52 in the corresponding design record 36 and adds said plant to the plant selection list 62 (512). In at least one embodiment, these steps (504)-(512) are repeated for a second “shrub” specimen plant 76.

In at least one embodiment, the computing system 22 orders the plants within the shrub list by maximum height 84 (514), then selects from the shrub list a pre-determined number of plants (based on the site dimensions 42, for example) having the greatest height—for example, the two tallest plants—and adds them to the plant selection list 62 (516). In at least one embodiment, the computing system 22 next orders the plants within the shrub list by bio value 92 (518), then selects from the shrub list a pre-determined number of plants having the greatest bio value 92—for example, the two greatest bio value 92 plants—and adds them to the plant selection list 62 (520). In at least one embodiment, the computing system 22 further selects from the shrub list a pre-determined number of plants (based on the site dimensions 42, for example) having both the next greatest bio value 92—for example, the two next greatest bio value 92 plants—and a different plant form 80 as compared to the plants selected in step (520) and adds them to the plant selection list 62 (522). In at least one embodiment, the computing system 22 further selects from the shrub list a pre-determined number of plants (based on the site dimensions 42, for example) having both the next greatest bio value 92—for example, the two next greatest bio value 92 plants—and a different plant color 78 as compared to the plants selected in step (522) and adds them to the plant selection list 62 (524). In at least one embodiment, the computing system 22 further selects from the shrub list a pre-determined number of plants (based on the site dimensions 42, for example) having the next greatest bio value 92—for example, the two next greatest bio value 92 plants—and adds them to the plant selection list 62 (526).

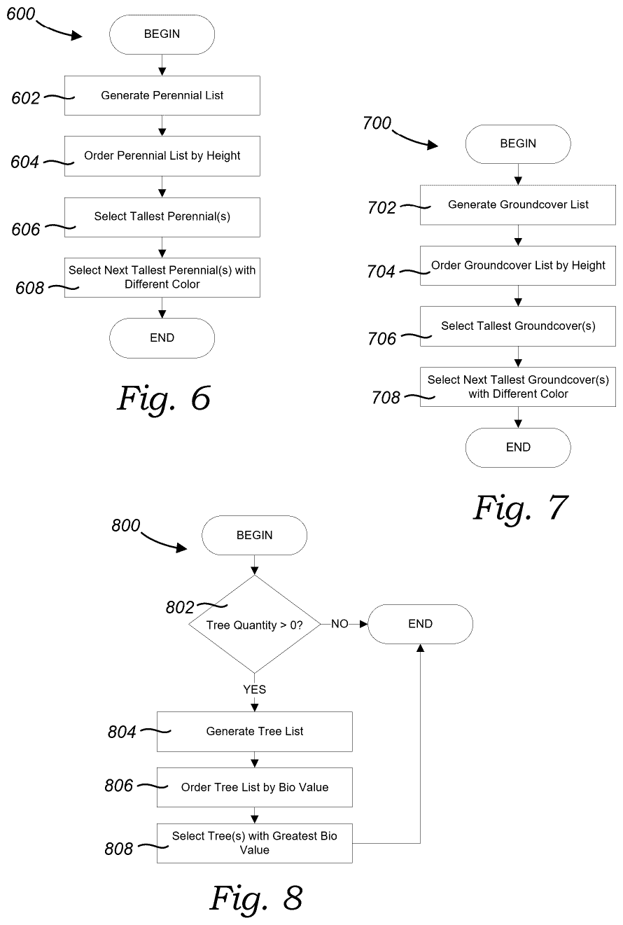

In at least one embodiment, as illustrated in the flow diagram of FIG. 6, the computing system 22 generates a perennial list comprising all plants in the compatible plant set having a “perennial” plant type 74 and a plant color 78 that matches one or more of the color preferences 52 in the corresponding design record 36 (602). In at least one embodiment, the computing system 22 orders the plants within the perennial list by maximum height 84 (604), then selects a pre-determined number of plants (based on the site dimensions 42, for example)—for example, two plants—having a maximum height 84 that is between the minimum plant height 46 and maximum plant height 48 in the corresponding design record 36 and adds them to the plant selection list 62 (606). In at least one embodiment, the computing system 22 further selects from the perennial list a pre-determined number of plants (based on the site dimensions 42, for example)—for example, two plants—having a maximum height 84 that is between the minimum plant height 46 and maximum plant height 48 in the corresponding design record 36 and a different plant color 78 as compared to the plants selected in step (606) and adds them to the plant selection list 62 (608).

In at least one embodiment, as illustrated in the flow diagram of FIG. 7, the computing system 22 generates a groundcover list comprising all plants in the compatible plant set having a “groundcover” plant type 74 and a plant color 78 that matches one or more of the color preferences 52 in the corresponding design record 36 (702). In at least one embodiment, the computing system 22 orders the plants within the groundcover list by maximum height 84 (704), then selects a pre-determined number of plants (based on the site dimensions 42, for example)—for example, two plants—having a maximum height 84 that is between the minimum plant height 46 and maximum plant height 48 in the corresponding design record 36 and adds them to the plant selection list 62 (706). In at least one embodiment, the computing system 22 further selects from the groundcover list a pre-determined number of plants (based on the site dimensions 42, for example)—for example, two plants—having a maximum height 84 that is between the minimum plant height 46 and maximum plant height 48 in the corresponding design record 36 and a different plant color 78 as compared to the plants selected in step (706) and adds them to the plant selection list 62 (708).

In at least one embodiment, as illustrated in the flow diagram of FIG. 8, where the tree quantity 56 of the corresponding design record 36 is greater than zero (802), the computing system 22 generates a tree list comprising all plants in the compatible plant set having a “tree” plant type 74 (804). In at least one embodiment, the computing system 22 orders the plants within the tree list by bio value 92 (806), then selects from the tree list a pre-determined number of plants (based on the site dimensions 42, for example) having the greatest bio value 92—for example, the single greatest bio value 92 plant—and adds them to the plant selection list 62 (808).

Referring again to FIG. 2, in at least one embodiment, with the plant selection list 62 compiled, the computing system 22 then communicates the plant selection list 62 as a landscape design report 94 to the user (214). In at least one embodiment, the landscape design report 94 is displayed on the display screen 34 of the user device 28. In at least one further embodiment, landscape design report 94 is transmitted electronically to the user via email, SMS text, push notification, etc. The user is then able to order the recommended plants from the plant selection list 62 and put the landscape design plan into action (or pass the plant selection list 62 on to a landscape designer to put the landscape design plan into action).

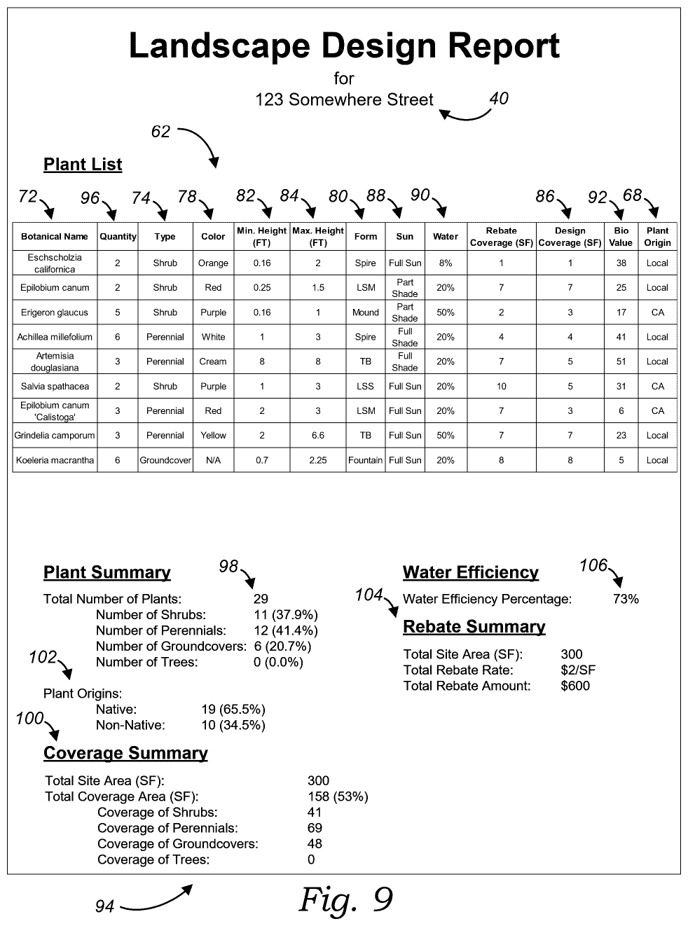

In at least one embodiment, as illustrated in FIG. 9, the computing system 22 adds further information to the landscape design report 94 prior to communicating the landscape design report 94 to the user. In at least one such embodiment, the landscape design report 94 includes one or more of: a plant quantity 96 of each plant in the plant selection list 62; a total plant count 98 for all of the plants in the plant selection list 62, along with a plant type 74 count for each plant type 74 in the plant selection list 62; respective percentages of plant types 74 in the plant selection list 62; a coverage summary 100 outlining the total coverage area 86 provided by all of the plants in the plant selection list 62, along with the total coverage area 86 provided by each plant type 74 in the plant selection list 62; an origin summary 102 outlining respective percentages of plant origins 68 for all of the plants in the plant selection list 62, along with respective percentages of plant origins 68 for each plant type 74 in the plant selection list 62; a rebate summary 104 outlining the total rebate amount for all of the plants in the plant selection list 62 based on the site dimensions 42 (typically as a dollar amount per square foot based on the square footage of the total coverage area 86 as compared to the site dimensions 42); and a water efficiency percentage 106 reflecting the amount of water saved by incorporating into the site the plants in the plant selection list 62 as compared to a traditional lawn or other plants that require relatively more water (based on the water requirement 90 for each plant in the plant selection list 62, the total plant count of the plants in the plant selection list 62, and the site dimensions 42 of the site).

In at least one further embodiment, the computing system 22 determines the ideal location within the site for each of the plants from the plant selection list 62, based on the data contained in the corresponding design record 36 and the plant selection list 62, and generates a visual design plan of the site that represents those locations. In at least one embodiment, the landscape design report 94 includes the visual design plan to assist the user in putting the landscape design plan into action.

Thus, in at least one embodiment, the computing system 22 takes into account all the requirements—location, design, user preference and the plants' biodiversity benefit—and can return the plant selection list 62 containing plants that meet the requirements in real-time. This, in turn, saves a tremendous amount of time compared to the traditional landscape design process, and can also better ensure that these water efficient landscape designs incorporate all-native or a high percentage of native plants, in addition to plants having high biodiversity values.

Aspects of the present specification may also be described as the following embodiments:

1. A method for dynamically generating an at least one water efficient landscape design, consisting of a plurality of water efficient plants, for an at least one site, the method comprising the steps of: implementing a central computing system configured for receiving and processing select data related to each of the at least one landscape design and corresponding site, the computing system in selective communication with an at least one landscape database; the computing system gathering from an at least one user and the at least one landscape database one or more of a site location, site dimensions, a site orientation, a minimum plant height, a maximum plant height, a sun exposure, color preferences, a native preference, a tree quantity, a plant preference list, an existing plant list, and a plant selection list associated with the at least one site; the computing system storing one or more of the site location, site dimensions, site orientation, minimum plant height, maximum plant height, sun exposure, color preferences, native preference, tree quantity, plant preference list, existing plant list, and plant selection list for each of the at least one site in a corresponding design record; the computing system accessing a plant table within the at least one landscape database to obtain select details on a plurality of plants to potentially include in the at least one landscape design, said details including one or more of a plant origin, a common name, a botanical name, a plant type, a specimen plant, plant colors, a plant form, a minimum height, a maximum height, a coverage area, a sun requirement, a water requirement, and a bio value; the computing system populating the plant selection list for the at least one site based on data contained in the corresponding design record and the at least one plant table, the process of populating said plant selection list comprising the steps of: (a) the computing system accessing the at least one plant table and identifying all plants within the plant table that are compatible with an environment of the site location associated with said site; (b) the computing system determining which of said identified plants within the plant table satisfy each of the minimum plant height, maximum plant height, color preferences, native preference, and plant preference list specified in the corresponding design record, and adding each of said identified plants to a compatible plant set; (c) the computing system ordering the plants within the compatible plant set by their respective maximum height, selecting a pre-determined number of plants from the compatible plant set having the greatest maximum height, and adding said plants to the plant selection list; (d) the computing system generating a shrub list comprising all plants in the compatible plant set having a “shrub” plant type and a plant color that matches one or more of the color preferences in the corresponding design record; (e) the computing system adding a specimen plant from the shrub list to the plant selection list; (f) the computing system ordering the plants within the shrub list by their respective maximum height, selecting a pre-determined number of plants from the shrub list having the greatest maximum height, and adding said plants to the plant selection list; (g) the computing system ordering the plants within the shrub list by their respective bio value, selecting a pre-determined number of plants having the greatest bio value, and adding said plants to the plant selection list; (h) the computing system selecting a pre-determined number of plants from the shrub list having the next greatest bio value and a different plant form as compared to the plants chosen in step (g), and adding said plants to the plant selection list; (i) the computing system selecting a pre-determined number of plants from the shrub list having the next greatest bio value and a different plant color as compared to the plants chosen in step (h), and adding said plants to the plant selection list; (j) the computing system selecting a pre-determined number of plants from the shrub list having the next greatest bio value as compared to the plants chosen in step (i), and adding said plants to the plant selection list; (k) the computing system generating a perennial list comprising all plants in the compatible plant set having a “perennial” plant type and a plant color that matches one or more of the color preferences in the corresponding design record; (l) the computing system ordering the plants within the perennial list by their respective maximum height, selecting a pre-determined number of plants from the perennial list having the greatest maximum height, and adding said plants to the plant selection list; (m) the computing system selecting a pre-determined number of plants from the perennial list having the next greatest maximum height and a different plant color as compared to the plants chosen in step (l), and adding said plants to the plant selection list; (n) the computing system generating a groundcover list comprising all plants in the compatible plant set having a “groundcover” plant type and a plant color that matches one or more of the color preferences in the corresponding design record; (o) the computing system ordering the plants within the groundcover list by their respective maximum height, selecting a pre-determined number of plants from the groundcover list having the greatest maximum height, and adding said plants to the plant selection list; (p) the computing system selecting a pre-determined number of plants from the groundcover list having the next greatest maximum height and a different plant color as compared to the plants chosen in step (o), and adding said plants to the plant selection list; (q) upon the computing system determining that the tree quantity value of the corresponding design record is greater than zero: the computing system generating a tree list comprising all plants in the compatible plant set having a “tree” plant type; and the computing system ordering the plants within the tree list by their respective bio value, selecting a pre-determined number of plants from the tree list having the greatest bio value, and adding said plants to the plant selection list; and the computing system communicating the plant selection list as a landscape design report to the at least one user.

2. The method according to embodiment 1, wherein the step of the computing system adding a specimen plant from the shrub list to the plant selection list further comprises the steps of: upon the computing system determining that only a single plant in the shrub list is a specimen plant, the computing system adding said plant to the plant selection list; upon the computing system determining that two or more plants in the shrub list are specimen plants, the computing system adding to the plant selection list the specimen plant having the greatest maximum height; and upon the computing system determining that no plants in the shrub list are a specimen plant, the computing system selecting a specimen plant from the at least one plant table having a “shrub” plant type and a plant color that matches one or more of the color preferences in the corresponding design record, and adding said plant to the plant selection list.

3. The method according to embodiments 1-2, wherein the step of the computing system adding a specimen plant from the shrub list to the plant selection list is repeated for a second “shrub” specimen plant.

4. The method according to embodiments 1-3, wherein the step of the computing system communicating the plant selection list as a landscape design report to the at least one user further comprises the step of the computing system displaying the landscape design report on a display screen of a user device in the possession of the at least one user.

5. The method according to embodiments 1-4, wherein the step of the computing system communicating the plant selection list as a landscape design report to the at least one user further comprises the step of the computing system transmitting the landscape design report electronically to a user device in the possession of the at least one user.

6. The method according to embodiments 1-5, further comprising the step of the computing system adding to the landscape design report one or more of a plant quantity of each plant in the plant selection list, a total plant count for all of the plants in the plant selection list, a plant type count for each plant type in the plant selection list, a percentage of each plant type in the plant selection list, a total coverage area provided by all of the plants in the plant selection list, a total coverage area provided by each plant type in the plant selection list, a percentage of each plant origin for all of the plants in the plant selection list, a percentage of each plant origin for each plant type in the plant selection list, a total rebate amount for all of the plants in the plant selection list, and a total rebate amount for each plant type in the plant selection list.

7. The method according to embodiments 1-6, further comprising the step of the computing system adding to the landscape design report a water efficiency percentage reflecting an amount of water saved by incorporating into the site the plants in the plant selection list as compared to a traditional lawn or other plants that require relatively more water.

8. The method according to embodiments 1-7, further comprising the step of implementing an at least one data storage device in communication with the computing system and configured for selectively storing said data related to each of the at least one landscape design and corresponding site.

9. A non-transitory computer readable medium containing program instructions for causing an at least one computing device to perform a method of dynamically generating an at least one water efficient landscape design, consisting of a plurality of water efficient plants, for an at least one site, the computing device in selective communication with an at least one landscape database and configured for receiving and processing select data related to each of the at least one landscape design and corresponding site, the method comprising the steps of: the computing device gathering from an at least one user and the at least one landscape database one or more of a site location, site dimensions, a site orientation, a minimum plant height, a maximum plant height, a sun exposure, color preferences, a native preference, a tree quantity, a plant preference list, an existing plant list, and a plant selection list associated with the at least one site; the computing device storing one or more of the site location, site dimensions, site orientation, minimum plant height, maximum plant height, sun exposure, color preferences, native preference, tree quantity, plant preference list, existing plant list, and plant selection list for each of the at least one site in a corresponding design record; the computing device accessing a plant table within the at least one landscape database to obtain select details on a plurality of plants to potentially include in the at least one landscape design, said details including one or more of a plant origin, a common name, a botanical name, a plant type, a specimen plant, plant colors, a plant form, a minimum height, a maximum height, a coverage area, a sun requirement, a water requirement, and a bio value; the computing device populating the plant selection list for the at least one site based on data contained in the corresponding design record and the at least one plant table, the process of populating said plant selection list comprising the steps of: (a) the computing device accessing the at least one plant table and identifying all plants within the plant table that are compatible with an environment of the site location associated with said site; (b) the computing device determining which of said identified plants within the plant table satisfy each of the minimum plant height, maximum plant height, color preferences, native preference, and plant preference list specified in the corresponding design record, and adding each of said identified plants to a compatible plant set; (c) the computing device ordering the plants within the compatible plant set by their respective maximum height, selecting a pre-determined number of plants from the compatible plant set having the greatest maximum height, and adding said plants to the plant selection list; (d) the computing device generating a shrub list comprising all plants in the compatible plant set having a “shrub” plant type and a plant color that matches one or more of the color preferences in the corresponding design record; (e) the computing device adding a specimen plant from the shrub list to the plant selection list; (f) the computing device ordering the plants within the shrub list by their respective maximum height, selecting a pre-determined number of plants from the shrub list having the greatest maximum height, and adding said plants to the plant selection list; (g) the computing device ordering the plants within the shrub list by their respective bio value, selecting a pre-determined number of plants having the greatest bio value, and adding said plants to the plant selection list; (h) the computing device selecting a pre-determined number of plants from the shrub list having the next greatest bio value and a different plant form as compared to the plants chosen in step (g), and adding said plants to the plant selection list; (i) the computing device selecting a pre-determined number of plants from the shrub list having the next greatest bio value and a different plant color as compared to the plants chosen in step (h), and adding said plants to the plant selection list; (j) the computing device selecting a pre-determined number of plants from the shrub list having the next greatest bio value as compared to the plants chosen in step (i), and adding said plants to the plant selection list; (k) the computing device generating a perennial list comprising all plants in the compatible plant set having a “perennial” plant type and a plant color that matches one or more of the color preferences in the corresponding design record; (l) the computing device ordering the plants within the perennial list by their respective maximum height, selecting a pre-determined number of plants from the perennial list having the greatest maximum height, and adding said plants to the plant selection list; (m) the computing device selecting a pre-determined number of plants from the perennial list having the next greatest maximum height and a different plant color as compared to the plants chosen in step (l), and adding said plants to the plant selection list; (n) the computing device generating a groundcover list comprising all plants in the compatible plant set having a “groundcover” plant type and a plant color that matches one or more of the color preferences in the corresponding design record; (o) the computing device ordering the plants within the groundcover list by their respective maximum height, selecting a pre-determined number of plants from the groundcover list having the greatest maximum height, and adding said plants to the plant selection list; (p) the computing device selecting a pre-determined number of plants from the groundcover list having the next greatest maximum height and a different plant color as compared to the plants chosen in step (o), and adding said plants to the plant selection list; (q) upon the computing device determining that the tree quantity value of the corresponding design record is greater than zero: the computing device generating a tree list comprising all plants in the compatible plant set having a “tree” plant type; and the computing device ordering the plants within the tree list by their respective bio value, selecting a pre-determined number of plants from the tree list having the greatest bio value, and adding said plants to the plant selection list; and the computing device communicating the plant selection list as a landscape design report to the at least one user.

10. The method according to embodiment 9, wherein the step of the computing device adding a specimen plant from the shrub list to the plant selection list further comprises the steps of: upon the computing device determining that only a single plant in the shrub list is a specimen plant, the computing device adding said plant to the plant selection list; upon the computing device determining that two or more plants in the shrub list are specimen plants, the computing device adding to the plant selection list the specimen plant having the greatest maximum height; and upon the computing device determining that no plants in the shrub list are a specimen plant, the computing device selecting a specimen plant from the at least one plant table having a “shrub” plant type and a plant color that matches one or more of the color preferences in the corresponding design record, and adding said plant to the plant selection list.

11. The method according to embodiments 9-10, wherein the step of the computing device adding a specimen plant from the shrub list to the plant selection list is repeated for a second “shrub” specimen plant.

12. The method according to embodiments 9-11, wherein the step of the computing device communicating the plant selection list as a landscape design report to the at least one user further comprises the step of the computing device displaying the landscape design report on a display screen of a user device in the possession of the at least one user.

13. The method according to embodiments 9-12, wherein the step of the computing device communicating the plant selection list as a landscape design report to the at least one user further comprises the step of the computing device transmitting the landscape design report electronically to a user device in the possession of the at least one user.

14. The method according to embodiments 9-13, further comprising the step of the computing device adding to the landscape design report one or more of a plant quantity of each plant in the plant selection list, a total plant count for all of the plants in the plant selection list, a plant type count for each plant type in the plant selection list, a percentage of each plant type in the plant selection list, a total coverage area provided by all of the plants in the plant selection list, a total coverage area provided by each plant type in the plant selection list, a percentage of each plant origin for all of the plants in the plant selection list, a percentage of each plant origin for each plant type in the plant selection list, a total rebate amount for all of the plants in the plant selection list, and a total rebate amount for each plant type in the plant selection list.

15. The method according to embodiments 9-14, further comprising the step of the computing device adding to the landscape design report a water efficiency percentage reflecting an amount of water saved by incorporating into the site the plants in the plant selection list as compared to a traditional lawn or other plants that require relatively more water.

16. The method according to embodiments 9-15, further comprising the step of implementing an at least one data storage device in communication with the computing device and configured for selectively storing said data related to each of the at least one landscape design and corresponding site.

17. A landscape design system for dynamically generating an at least one water efficient landscape design, consisting of a plurality of water efficient plants, for an at least one site, the system comprising: an at least one computing device configured for receiving and processing select data related to each of the at least one landscape design and corresponding site, the computing device in selective communication with an at least one landscape database; wherein, the at least one computing device is further configured for: gathering from an at least one user and the at least one landscape database one or more of a site location, site dimensions, a site orientation, a minimum plant height, a maximum plant height, a sun exposure, color preferences, a native preference, a tree quantity, a plant preference list, an existing plant list, and a plant selection list associated with the at least one site; storing one or more of the site location, site dimensions, site orientation, minimum plant height, maximum plant height, sun exposure, color preferences, native preference, tree quantity, plant preference list, existing plant list, and plant selection list for each of the at least one site in a corresponding design record; accessing a plant table within the at least one landscape database to obtain select details on a plurality of plants to potentially include in the at least one landscape design, said details including one or more of a plant origin, a common name, a botanical name, a plant type, a specimen plant, plant colors, a plant form, a minimum height, a maximum height, a coverage area, a sun requirement, a water requirement, and a bio value; populating the plant selection list for the at least one site based on data contained in the corresponding design record and the at least one plant table, the process of populating said plant selection list comprising the steps of: (a) accessing the at least one plant table and identifying all plants within the plant table that are compatible with an environment of the site location associated with said site; (b) determining which of said identified plants within the plant table satisfy each of the minimum plant height, maximum plant height, color preferences, native preference, and plant preference list specified in the corresponding design record, and adding each of said identified plants to a compatible plant set; (c) ordering the plants within the compatible plant set by their respective maximum height, selecting a pre-determined number of plants from the compatible plant set having the greatest maximum height, and adding said plants to the plant selection list; (d) generating a shrub list comprising all plants in the compatible plant set having a “shrub” plant type and a plant color that matches one or more of the color preferences in the corresponding design record; (e) adding a specimen plant from the shrub list to the plant selection list; (f) ordering the plants within the shrub list by their respective maximum height, selecting a pre-determined number of plants from the shrub list having the greatest maximum height, and adding said plants to the plant selection list; (g) ordering the plants within the shrub list by their respective bio value, selecting a pre-determined number of plants having the greatest bio value, and adding said plants to the plant selection list; (h) selecting a pre-determined number of plants from the shrub list having the next greatest bio value and a different plant form as compared to the plants chosen in step (g), and adding said plants to the plant selection list; (i) selecting a pre-determined number of plants from the shrub list having the next greatest bio value and a different plant color as compared to the plants chosen in step (h), and adding said plants to the plant selection list; (j) selecting a pre-determined number of plants from the shrub list having the next greatest bio value as compared to the plants chosen in step (i), and adding said plants to the plant selection list; (k) generating a perennial list comprising all plants in the compatible plant set having a “perennial” plant type and a plant color that matches one or more of the color preferences in the corresponding design record; (l) ordering the plants within the perennial list by their respective maximum height, selecting a pre-determined number of plants from the perennial list having the greatest maximum height, and adding said plants to the plant selection list; (m) selecting a pre-determined number of plants from the perennial list having the next greatest maximum height and a different plant color as compared to the plants chosen in step (l), and adding said plants to the plant selection list; (n) generating a groundcover list comprising all plants in the compatible plant set having a “groundcover” plant type and a plant color that matches one or more of the color preferences in the corresponding design record; (o) ordering the plants within the groundcover list by their respective maximum height, selecting a pre-determined number of plants from the groundcover list having the greatest maximum height, and adding said plants to the plant selection list; (p) selecting a pre-determined number of plants from the groundcover list having the next greatest maximum height and a different plant color as compared to the plants chosen in step (o), and adding said plants to the plant selection list; (q) upon determining that the tree quantity value of the corresponding design record is greater than zero: generating a tree list comprising all plants in the compatible plant set having a “tree” plant type; and ordering the plants within the tree list by their respective bio value, selecting a pre-determined number of plants from the tree list having the greatest bio value, and adding said plants to the plant selection list; and communicating the plant selection list as a landscape design report to the at least one user.

18. The landscape design system according to embodiment 17, wherein while adding a specimen plant from the shrub list to the plant selection list, the computing device is further configured for: upon determining that only a single plant in the shrub list is a specimen plant, adding said plant to the plant selection list; upon determining that two or more plants in the shrub list are specimen plants, adding to the plant selection list the specimen plant having the greatest maximum height; and upon determining that no plants in the shrub list are a specimen plant, selecting a specimen plant from the at least one plant table having a “shrub” plant type and a plant color that matches one or more of the color preferences in the corresponding design record, and adding said plant to the plant selection list.

19. The landscape design system according to embodiments 17-18, wherein the computing device is further configured for adding a specimen plant from the shrub list to the plant selection list for a second “shrub” specimen plant.

20. The landscape design system according to embodiments 17-19, wherein while communicating the plant selection list as a landscape design report to the at least one user, the computing device is further configured for displaying the landscape design report on a display screen of a user device in the possession of the at least one user.

21. The landscape design system according to embodiments 17-20, wherein while communicating the plant selection list as a landscape design report to the at least one user, the computing device is further configured for transmitting the landscape design report electronically to a user device in the possession of the at least one user.

22. The landscape design system according to embodiments 17-21, wherein the computing device is further configured adding to the landscape design report one or more of a plant quantity of each plant in the plant selection list, a total plant count for all of the plants in the plant selection list, a plant type count for each plant type in the plant selection list, a percentage of each plant type in the plant selection list, a total coverage area provided by all of the plants in the plant selection list, a total coverage area provided by each plant type in the plant selection list, a percentage of each plant origin for all of the plants in the plant selection list, a percentage of each plant origin for each plant type in the plant selection list, a total rebate amount for all of the plants in the plant selection list, and a total rebate amount for each plant type in the plant selection list.

23. The landscape design system according to embodiments 17-22, wherein the computing device is further configured for adding to the landscape design report a water efficiency percentage reflecting an amount of water saved by incorporating into the site the plants in the plant selection list as compared to a traditional lawn or other plants that require relatively more water.

24. The landscape design system according to embodiments 17-23, further comprising an at least one data storage device in communication with the computing device and configured for selectively storing said data related to each of the at least one landscape design and corresponding site.

In closing, regarding the exemplary embodiments of the present invention as shown and described herein, it will be appreciated that a system and associated methods are disclosed and configured for dynamically generating water efficient landscape designs. Because the principles of the invention may be practiced in a number of configurations beyond those shown and described, it is to be understood that the invention is not in any way limited by the exemplary embodiments, but is generally directed to a landscape design system and is able to take numerous forms to do so without departing from the spirit and scope of the invention. It will also be appreciated by those skilled in the art that the present invention is not limited to the particular geometries and materials of construction disclosed, but may instead entail other functionally comparable structures or materials, now known or later developed, without departing from the spirit and scope of the invention.

Certain embodiments of the present invention are described herein, including the best mode known to the inventor(s) for carrying out the invention. Of course, variations on these described embodiments will become apparent to those of ordinary skill in the art upon reading the foregoing description. The inventor(s) expect skilled artisans to employ such variations as appropriate, and the inventor(s) intend for the present invention to be practiced otherwise than specifically described herein. Accordingly, this invention includes all modifications and equivalents of the subject matter recited in the claims appended hereto as permitted by applicable law. Moreover, any combination of the above-described embodiments in all possible variations thereof is encompassed by the invention unless otherwise indicated herein or otherwise clearly contradicted by context.

Groupings of alternative embodiments, elements, or steps of the present invention are not to be construed as limitations. Each group member may be referred to and claimed individually or in any combination with other group members disclosed herein. It is anticipated that one or more members of a group may be included in, or deleted from, a group for reasons of convenience and/or patentability. When any such inclusion or deletion occurs, the specification is deemed to contain the group as modified thus fulfilling the written description of all Markush groups used in the appended claims.

Unless otherwise indicated, all numbers expressing a characteristic, item, quantity, parameter, property, term, and so forth used in the present specification and claims are to be understood as being modified in all instances by the terms “about” and “approximately.” As used herein, the terms “about” and “approximately” mean that the characteristic, item, quantity, parameter, property, or term so qualified encompasses a range of plus or minus ten percent above and below the value of the stated characteristic, item, quantity, parameter, property, or term. Accordingly, unless indicated to the contrary, the numerical parameters set forth in the specification and attached claims are approximations that may vary. At the very least, and not as an attempt to limit the application of the doctrine of equivalents to the scope of the claims, each numerical indication should at least be construed in light of the number of reported significant digits and by applying ordinary rounding techniques. Notwithstanding that the numerical ranges and values setting forth the broad scope of the invention are approximations, the numerical ranges and values set forth in the specific examples are reported as precisely as possible. Any numerical range or value, however, inherently contains certain errors necessarily resulting from the standard deviation found in their respective testing measurements. Recitation of numerical ranges of values herein is merely intended to serve as a shorthand method of referring individually to each separate numerical value falling within the range. Unless otherwise indicated herein, each individual value of a numerical range is incorporated into the present specification as if it were individually recited herein. Similarly, as used herein, unless indicated to the contrary, the term “substantially” is a term of degree intended to indicate an approximation of the characteristic, item, quantity, parameter, property, or term so qualified, encompassing a range that can be understood and construed by those of ordinary skill in the art, or at least encompassing a range of plus or minus ten percent above and below the value of the stated characteristic, item, quantity, parameter, property, or term.

Use of the terms “may” or “can” in reference to an embodiment or aspect of an embodiment also carries with it the alternative meaning of “may not” or “cannot.” As such, if the present specification discloses that an embodiment or an aspect of an embodiment may be or can be included as part of the inventive subject matter, then the negative limitation or exclusionary proviso is also explicitly meant, meaning that an embodiment or an aspect of an embodiment may not be or cannot be included as part of the inventive subject matter. In a similar manner, use of the term “optionally” in reference to an embodiment or aspect of an embodiment means that such embodiment or aspect of the embodiment may be included as part of the inventive subject matter or may not be included as part of the inventive subject matter. Whether such a negative limitation or exclusionary proviso applies will be based on whether the negative limitation or exclusionary proviso is recited in the claimed subject matter.

The terms “a,” “an,” “the” and similar references used in the context of describing the present invention (especially in the context of the following claims) are to be construed to cover both the singular and the plural, unless otherwise indicated herein or clearly contradicted by context. Further, ordinal indicators—such as “first,” “second,” “third,” etc.—for identified elements are used to distinguish between the elements, and do not indicate or imply a required or limited number of such elements, and do not indicate a particular position or order of such elements unless otherwise specifically stated. All methods described herein can be performed in any suitable order unless otherwise indicated herein or otherwise clearly contradicted by context. The use of any and all examples, or exemplary language (e.g., “such as”) provided herein is intended merely to better illuminate the present invention and does not pose a limitation on the scope of the invention otherwise claimed. No language in the present specification should be construed as indicating any non-claimed element essential to the practice of the invention.

When used in the claims, whether as filed or added per amendment, the open-ended transitional term “comprising” (along with equivalent open-ended transitional phrases thereof such as “including,” “containing” and “having”) encompasses all the expressly recited elements, limitations, steps and/or features alone or in combination with un-recited subject matter; the named elements, limitations and/or features are essential, but other unnamed elements, limitations and/or features may be added and still form a construct within the scope of the claim. Specific embodiments disclosed herein may be further limited in the claims using the closed-ended transitional phrases “consisting of” or “consisting essentially of” in lieu of or as an amendment for “comprising.” When used in the claims, whether as filed or added per amendment, the closed-ended transitional phrase “consisting of” excludes any element, limitation, step, or feature not expressly recited in the claims. The closed-ended transitional phrase “consisting essentially of” limits the scope of a claim to the expressly recited elements, limitations, steps and/or features and any other elements, limitations, steps and/or features that do not materially affect the basic and novel characteristic(s) of the claimed subject matter. Thus, the meaning of the open-ended transitional phrase “comprising” is being defined as encompassing all the specifically recited elements, limitations, steps and/or features as well as any optional, additional unspecified ones. The meaning of the closed-ended transitional phrase “consisting of” is being defined as only including those elements, limitations, steps and/or features specifically recited in the claim, whereas the meaning of the closed-ended transitional phrase “consisting essentially of” is being defined as only including those elements, limitations, steps and/or features specifically recited in the claim and those elements, limitations, steps and/or features that do not materially affect the basic and novel characteristic(s) of the claimed subject matter. Therefore, the open-ended transitional phrase “comprising” (along with equivalent open-ended transitional phrases thereof) includes within its meaning, as a limiting case, claimed subject matter specified by the closed-ended transitional phrases “consisting of” or “consisting essentially of.” As such, embodiments described herein or so claimed with the phrase “comprising” are expressly or inherently unambiguously described, enabled and supported herein for the phrases “consisting essentially of” and “consisting of.”

Any claims intended to be treated under 35 U.S.C. §112(f) will begin with the words “means for,” but use of the term “for” in any other context is not intended to invoke treatment under 35 U.S.C. §112(f). Accordingly, Applicant reserves the right to pursue additional claims after filing this application, in either this application or in a continuing application.

It should be understood that any logic code, programs, modules, processes, and/or methods disclosed herein, along with the order in which the respective elements of any such method are performed, are purely exemplary. Depending on the implementation, they may be performed in any order or in parallel, unless indicated otherwise in the present disclosure. Further, the logic code is not related, or limited to any particular programming language, and may comprise one or more modules that execute on one or more processors in a distributed, non-distributed, or multiprocessing environment. Additionally, the various illustrative logical blocks, modules, methods, and algorithm processes and sequences described in connection with the embodiments disclosed herein can be implemented as electronic hardware, computer software, or combinations of both. To clearly illustrate this interchangeability of hardware and software, various illustrative components, blocks, modules, and process actions have been described above generally in terms of their functionality. Whether such functionality is implemented as hardware or software depends upon the particular application and design constraints imposed on the overall system. The described functionality can be implemented in varying ways for each particular application, but such implementation decisions should not be interpreted as causing a departure from the scope of this document.

The phrase “non-transitory,” in addition to having its ordinary meaning, as used in this document means “enduring or long-lived”. The phrase “non-transitory computer readable medium,” in addition to having its ordinary meaning, includes any and all computer readable mediums, with the sole exception of a transitory, propagating signal. This includes, by way of example and not limitation, non-transitory computer-readable mediums such as register memory, processor cache and random-access memory (“RAM”).

The methods as described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multi-chip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

All patents, patent publications, and other publications referenced and identified in the present specification are individually and expressly incorporated herein by reference in their entirety for the purpose of describing and disclosing, for example, the compositions and methodologies described in such publications that might be used in connection with the present invention. These publications are provided solely for their disclosure prior to the filing date of the present application. Nothing in this regard should be construed as an admission that the inventors are not entitled to antedate such disclosure by virtue of prior invention or for any other reason. All statements as to the date or representation as to the contents of these documents are based on the information available to the applicants and does not constitute any admission as to the correctness of the dates or contents of these documents.

While aspects of the invention have been described with reference to at least one exemplary embodiment, it is to be clearly understood by those skilled in the art that the invention is not limited thereto. Rather, the scope of the invention is to be interpreted only in conjunction with the appended claims and it is made clear, here, that the inventor(s) believe that the claimed subject matter is the invention.

All of the material in this patent document issue subject to copyright protection under the copyright laws of the United States and other countries. The copyright owner has no objection to the facsimile reproduction by anyone of the patent document or the patent disclosure, as it appears in official governmental records but, otherwise, all other copyright rights whatsoever are reserved.

What is claimed is:

1. A method for dynamically generating an at least one water efficient landscape design, consisting of a plurality of water efficient plants, for an at least one site, the method comprising the steps of:
implementing a central computing system configured for receiving and processing select data related to each of the at least one landscape design and corresponding site, the computing system in selective communication with an at least one landscape database;
the computing system gathering from an at least one user and the at least one landscape database one or more of a site location, site dimensions, a site orientation, a minimum plant height, a maximum plant height, a sun exposure, color preferences, a native preference, a tree quantity, a plant preference list, an existing plant list, and a plant selection list associated with the at least one site;
the computing system storing one or more of the site location, site dimensions, site orientation, minimum plant height, maximum plant height, sun exposure, color preferences, native preference, tree quantity, plant preference list, existing plant list, and plant selection list for each of the at least one site in a corresponding design record;
the computing system accessing a plant table within the at least one landscape database to obtain select details on a plurality of plants to potentially include in the at least one landscape design, said details including one or more of a plant origin, a common name, a botanical name, a plant type, a specimen plant, plant colors, a plant form, a minimum height, a maximum height, a coverage area, a sun requirement, a water requirement, and a bio value;
the computing system populating the plant selection list for the at least one site based on data contained in the corresponding design record and the at least one plant table, the process of populating said plant selection list comprising the steps of:
(a) the computing system accessing the at least one plant table and identifying all plants within the plant table that are compatible with an environment of the site location associated with said site;
(b) the computing system determining which of said identified plants within the plant table satisfy each of the minimum plant height, maximum plant height, color preferences, native preference, and plant preference list specified in the corresponding design record, and adding each of said identified plants to a compatible plant set;
(c) the computing system ordering the plants within the compatible plant set by their respective maximum height, selecting a pre-determined number of plants from the compatible plant set having the greatest maximum height, and adding said plants to the plant selection list;
(d) the computing system generating a shrub list comprising all plants in the compatible plant set having a “shrub” plant type and a plant color that matches one or more of the color preferences in the corresponding design record;
(e) the computing system adding a specimen plant from the shrub list to the plant selection list;
(f) the computing system ordering the plants within the shrub list by their respective maximum height, selecting a pre-determined number of plants from the shrub list having the greatest maximum height, and adding said plants to the plant selection list;
(g) the computing system ordering the plants within the shrub list by their respective bio value, selecting a pre-determined number of plants having the greatest bio value, and adding said plants to the plant selection list;
(h) the computing system selecting a pre-determined number of plants from the shrub list having the next greatest bio value and a different plant form as compared to the plants chosen in step (g), and adding said plants to the plant selection list;
(i) the computing system selecting a pre-determined number of plants from the shrub list having the next greatest bio value and a different plant color as compared to the plants chosen in step (h), and adding said plants to the plant selection list;
(j) the computing system selecting a pre-determined number of plants from the shrub list having the next greatest bio value as compared to the plants chosen in step (i), and adding said plants to the plant selection list;
(k) the computing system generating a perennial list comprising all plants in the compatible plant set having a “perennial” plant type and a plant color that matches one or more of the color preferences in the corresponding design record;
(l) the computing system ordering the plants within the perennial list by their respective maximum height, selecting a pre-determined number of plants from the perennial list having the greatest maximum height, and adding said plants to the plant selection list;
(m) the computing system selecting a pre-determined number of plants from the perennial list having the next greatest maximum height and a different plant color as compared to the plants chosen in step (l), and adding said plants to the plant selection list;
(n) the computing system generating a groundcover list comprising all plants in the compatible plant set having a “groundcover” plant type and a plant color that matches one or more of the color preferences in the corresponding design record;
(o) the computing system ordering the plants within the groundcover list by their respective maximum height, selecting a pre-determined number of plants from the groundcover list having the greatest maximum height, and adding said plants to the plant selection list;
(p) the computing system selecting a pre-determined number of plants from the groundcover list having the next greatest maximum height and a different plant color as compared to the plants chosen in step (o), and adding said plants to the plant selection list;
(q) upon the computing system determining that the tree quantity value of the corresponding design record is greater than zero:
the computing system generating a tree list comprising all plants in the compatible plant set having a “tree” plant type; and
the computing system ordering the plants within the tree list by their respective bio value, selecting a pre-determined number of plants from the tree list having the greatest bio value, and adding said plants to the plant selection list; and
the computing system communicating the plant selection list as a landscape design report to the at least one user.

2. The method of claim 1, wherein the step of the computing system adding a specimen plant from the shrub list to the plant selection list further comprises the steps of:
upon the computing system determining that only a single plant in the shrub list is a specimen plant, the computing system adding said plant to the plant selection list;
upon the computing system determining that two or more plants in the shrub list are specimen plants, the computing system adding to the plant selection list the specimen plant having the greatest maximum height; and
upon the computing system determining that no plants in the shrub list are a specimen plant, the computing system selecting a specimen plant from the at least one plant table having a “shrub” plant type and a plant color that matches one or more of the color preferences in the corresponding design record, and adding said plant to the plant selection list.

3. The method of claim 2, wherein the step of the computing system adding a specimen plant from the shrub list to the plant selection list is repeated for a second “shrub” specimen plant.

4. The method of claim 1, wherein the step of the computing system communicating the plant selection list as a landscape design report to the at least one user further comprises the step of the computing system displaying the landscape design report on a display screen of a user device in the possession of the at least one user.

5. The method of claim 1, wherein the step of the computing system communicating the plant selection list as a landscape design report to the at least one user further comprises the step of the computing system transmitting the landscape design report electronically to a user device in the possession of the at least one user.

6. The method of claim 1, further comprising the step of the computing system adding to the landscape design report one or more of a plant quantity of each plant in the plant selection list, a total plant count for all of the plants in the plant selection list, a plant type count for each plant type in the plant selection list, a percentage of each plant type in the plant selection list, a total coverage area provided by all of the plants in the plant selection list, a total coverage area provided by each plant type in the plant selection list, a percentage of each plant origin for all of the plants in the plant selection list, a percentage of each plant origin for each plant type in the plant selection list, a total rebate amount for all of the plants in the plant selection list, and a total rebate amount for each plant type in the plant selection list.

7. The method of claim 1, further comprising the step of the computing system adding to the landscape design report a water efficiency percentage reflecting an amount of water saved by incorporating into the site the plants in the plant selection list as compared to a traditional lawn or other plants that require relatively more water.

8. A non-transitory computer readable medium containing program instructions for causing an at least one computing device to perform a method of dynamically generating an at least one water efficient landscape design, consisting of a plurality of water efficient plants, for an at least one site, the computing device in selective communication with an at least one landscape database and configured for receiving and processing select data related to each of the at least one landscape design and corresponding site, the method comprising the steps of:
the computing device gathering from an at least one user and the at least one landscape database one or more of a site location, site dimensions, a site orientation, a minimum plant height, a maximum plant height, a sun exposure, color preferences, a native preference, a tree quantity, a plant preference list, an existing plant list, and a plant selection list associated with the at least one site;
the computing device storing one or more of the site location, site dimensions, site orientation, minimum plant height, maximum plant height, sun exposure, color preferences, native preference, tree quantity, plant preference list, existing plant list, and plant selection list for each of the at least one site in a corresponding design record;
the computing device accessing a plant table within the at least one landscape database to obtain select details on a plurality of plants to potentially include in the at least one landscape design, said details including one or more of a plant origin, a common name, a botanical name, a plant type, a specimen plant, plant colors, a plant form, a minimum height, a maximum height, a coverage area, a sun requirement, a water requirement, and a bio value;
the computing device populating the plant selection list for the at least one site based on data contained in the corresponding design record and the at least one plant table, the process of populating said plant selection list comprising the steps of:
(a) the computing device accessing the at least one plant table and identifying all plants within the plant table that are compatible with an environment of the site location associated with said site;
(b) the computing device determining which of said identified plants within the plant table satisfy each of the minimum plant height, maximum plant height, color preferences, native preference, and plant preference list specified in the corresponding design record, and adding each of said identified plants to a compatible plant set;
(c) the computing device ordering the plants within the compatible plant set by their respective maximum height, selecting a pre-determined number of plants from the compatible plant set having the greatest maximum height, and adding said plants to the plant selection list;
(d) the computing device generating a shrub list comprising all plants in the compatible plant set having a “shrub” plant type and a plant color that matches one or more of the color preferences in the corresponding design record;
(e) the computing device adding a specimen plant from the shrub list to the plant selection list;
(f) the computing device ordering the plants within the shrub list by their respective maximum height, selecting a pre-determined number of plants from the shrub list having the greatest maximum height, and adding said plants to the plant selection list;
(g) the computing device ordering the plants within the shrub list by their respective bio value, selecting a pre-determined number of plants having the greatest bio value, and adding said plants to the plant selection list;
(h) the computing device selecting a pre-determined number of plants from the shrub list having the next greatest bio value and a different plant form as compared to the plants chosen in step (g), and adding said plants to the plant selection list;
(i) the computing device selecting a pre-determined number of plants from the shrub list having the next greatest bio value and a different plant color as compared to the plants chosen in step (h), and adding said plants to the plant selection list;
(j) the computing device selecting a pre-determined number of plants from the shrub list having the next greatest bio value as compared to the plants chosen in step (i), and adding said plants to the plant selection list;
(k) the computing device generating a perennial list comprising all plants in the compatible plant set having a “perennial” plant type and a plant color that matches one or more of the color preferences in the corresponding design record;
(l) the computing device ordering the plants within the perennial list by their respective maximum height, selecting a pre-determined number of plants from the perennial list having the greatest maximum height, and adding said plants to the plant selection list;
(m) the computing device selecting a pre-determined number of plants from the perennial list having the next greatest maximum height and a different plant color as compared to the plants chosen in step (l), and adding said plants to the plant selection list;
(n) the computing device generating a groundcover list comprising all plants in the compatible plant set having a “groundcover” plant type and a plant color that matches one or more of the color preferences in the corresponding design record;
(o) the computing device ordering the plants within the groundcover list by their respective maximum height, selecting a pre-determined number of plants from the groundcover list having the greatest maximum height, and adding said plants to the plant selection list;
(p) the computing device selecting a pre-determined number of plants from the groundcover list having the next greatest maximum height and a different plant color as compared to the plants chosen in step (o), and adding said plants to the plant selection list;
(q) upon the computing device determining that the tree quantity value of the corresponding design record is greater than zero:
the computing device generating a tree list comprising all plants in the compatible plant set having a “tree” plant type; and
the computing device ordering the plants within the tree list by their respective bio value, selecting a pre-determined number of plants from the tree list having the greatest bio value, and adding said plants to the plant selection list; and
the computing device communicating the plant selection list as a landscape design report to the at least one user.

9. The method of claim 8, wherein the step of the computing device adding a specimen plant from the shrub list to the plant selection list further comprises the steps of:
upon the computing device determining that only a single plant in the shrub list is a specimen plant, the computing device adding said plant to the plant selection list;
upon the computing device determining that two or more plants in the shrub list are specimen plants, the computing device adding to the plant selection list the specimen plant having the greatest maximum height; and
upon the computing device determining that no plants in the shrub list are a specimen plant, the computing device selecting a specimen plant from the at least one plant table having a “shrub” plant type and a plant color that matches one or more of the color preferences in the corresponding design record, and adding said plant to the plant selection list.

10. The method of claim 9, wherein the step of the computing device adding a specimen plant from the shrub list to the plant selection list is repeated for a second “shrub” specimen plant.

11. The method of claim 8, wherein the step of the computing device communicating the plant selection list as a landscape design report to the at least one user further comprises the step of the computing device displaying the landscape design report on a display screen of a user device in the possession of the at least one user.

12. The method of claim 8, wherein the step of the computing device communicating the plant selection list as a landscape design report to the at least one user further comprises the step of the computing device transmitting the landscape design report electronically to a user device in the possession of the at least one user.

13. The method of claim 8, further comprising the step of the computing device adding to the landscape design report one or more of a plant quantity of each plant in the plant selection list, a total plant count for all of the plants in the plant selection list, a plant type count for each plant type in the plant selection list, a percentage of each plant type in the plant selection list, a total coverage area provided by all of the plants in the plant selection list, a total coverage area provided by each plant type in the plant selection list, a percentage of each plant origin for all of the plants in the plant selection list, a percentage of each plant origin for each plant type in the plant selection list, a total rebate amount for all of the plants in the plant selection list, and a total rebate amount for each plant type in the plant selection list.

14. The method of claim 8, further comprising the step of the computing device adding to the landscape design report a water efficiency percentage reflecting an amount of water saved by incorporating into the site the plants in the plant selection list as compared to a traditional lawn or other plants that require relatively more water.

15. A landscape design system for dynamically generating an at least one water efficient landscape design, consisting of a plurality of water efficient plants, for an at least one site, the system comprising:
an at least one computing device configured for receiving and processing select data related to each of the at least one landscape design and corresponding site, the computing device in selective communication with an at least one landscape database;
wherein, the at least one computing device is further configured for:
gathering from an at least one user and the at least one landscape database one or more of a site location, site dimensions, a site orientation, a minimum plant height, a maximum plant height, a sun exposure, color preferences, a native preference, a tree quantity, a plant preference list, an existing plant list, and a plant selection list associated with the at least one site;
storing one or more of the site location, site dimensions, site orientation, minimum plant height, maximum plant height, sun exposure, color preferences, native preference, tree quantity, plant preference list, existing plant list, and plant selection list for each of the at least one site in a corresponding design record;
accessing a plant table within the at least one landscape database to obtain select details on a plurality of plants to potentially include in the at least one landscape design, said details including one or more of a plant origin, a common name, a botanical name, a plant type, a specimen plant, plant colors, a plant form, a minimum height, a maximum height, a coverage area, a sun requirement, a water requirement, and a bio value;
populating the plant selection list for the at least one site based on data contained in the corresponding design record and the at least one plant table, the process of populating said plant selection list comprising the steps of:
(a) accessing the at least one plant table and identifying all plants within the plant table that are compatible with an environment of the site location associated with said site;
(b) determining which of said identified plants within the plant table satisfy each of the minimum plant height, maximum plant height, color preferences, native preference, and plant preference list specified in the corresponding design record, and adding each of said identified plants to a compatible plant set;
(c) ordering the plants within the compatible plant set by their respective maximum height, selecting a pre-determined number of plants from the compatible plant set having the greatest maximum height, and adding said plants to the plant selection list;
(d) generating a shrub list comprising all plants in the compatible plant set having a “shrub” plant type and a plant color that matches one or more of the color preferences in the corresponding design record;
(e) adding a specimen plant from the shrub list to the plant selection list;
(f) ordering the plants within the shrub list by their respective maximum height, selecting a pre-determined number of plants from the shrub list having the greatest maximum height, and adding said plants to the plant selection list;
(g) ordering the plants within the shrub list by their respective bio value, selecting a pre-determined number of plants having the greatest bio value, and adding said plants to the plant selection list;
(h) selecting a pre-determined number of plants from the shrub list having the next greatest bio value and a different plant form as compared to the plants chosen in step (g), and adding said plants to the plant selection list;
(i) selecting a pre-determined number of plants from the shrub list having the next greatest bio value and a different plant color as compared to the plants chosen in step (h), and adding said plants to the plant selection list;
(j) selecting a pre-determined number of plants from the shrub list having the next greatest bio value as compared to the plants chosen in step (i), and adding said plants to the plant selection list;
(k) generating a perennial list comprising all plants in the compatible plant set having a “perennial” plant type and a plant color that matches one or more of the color preferences in the corresponding design record;
(l) ordering the plants within the perennial list by their respective maximum height, selecting a pre-determined number of plants from the perennial list having the greatest maximum height, and adding said plants to the plant selection list;
(m) selecting a pre-determined number of plants from the perennial list having the next greatest maximum height and a different plant color as compared to the plants chosen in step (l), and adding said plants to the plant selection list;
(n) generating a groundcover list comprising all plants in the compatible plant set having a “groundcover” plant type and a plant color that matches one or more of the color preferences in the corresponding design record;
(o) ordering the plants within the groundcover list by their respective maximum height, selecting a pre-determined number of plants from the groundcover list having the greatest maximum height, and adding said plants to the plant selection list;
(p) selecting a pre-determined number of plants from the groundcover list having the next greatest maximum height and a different plant color as compared to the plants chosen in step (o), and adding said plants to the plant selection list;
(q) upon determining that the tree quantity value of the corresponding design record is greater than zero:
generating a tree list comprising all plants in the compatible plant set having a “tree” plant type; and
ordering the plants within the tree list by their respective bio value, selecting a pre-determined number of plants from the tree list having the greatest bio value, and adding said plants to the plant selection list; and
communicating the plant selection list as a landscape design report to the at least one user.

16. The landscape design system of claim 15, wherein while adding a specimen plant from the shrub list to the plant selection list, the computing device is further configured for:
upon determining that only a single plant in the shrub list is a specimen plant, adding said plant to the plant selection list;
upon determining that two or more plants in the shrub list are specimen plants, adding to the plant selection list the specimen plant having the greatest maximum height; and
upon determining that no plants in the shrub list are a specimen plant, selecting a specimen plant from the at least one plant table having a “shrub” plant type and a plant color that matches one or more of the color preferences in the corresponding design record, and adding said plant to the plant selection list.

17. The landscape design system of claim 16, wherein the computing device is further configured for adding a specimen plant from the shrub list to the plant selection list for a second “shrub” specimen plant.

18. The landscape design system of claim 15, wherein the computing device is further configured adding to the landscape design report one or more of a plant quantity of each plant in the plant selection list, a total plant count for all of the plants in the plant selection list, a plant type count for each plant type in the plant selection list, a percentage of each plant type in the plant selection list, a total coverage area provided by all of the plants in the plant selection list, a total coverage area provided by each plant type in the plant selection list, a percentage of each plant origin for all of the plants in the plant selection list, a percentage of each plant origin for each plant type in the plant selection list, a total rebate amount for all of the plants in the plant selection list, and a total rebate amount for each plant type in the plant selection list.

19. The landscape design system of claim 15, wherein the computing device is further configured for adding to the landscape design report a water efficiency percentage reflecting an amount of water saved by incorporating into the site the plants in the plant selection list as compared to a traditional lawn or other plants that require relatively more water.

20. The landscape design system of claim 15, further comprising an at least one data storage device in communication with the computing device and configured for selectively storing said data related to each of the at least one landscape design and corresponding site.
